(19) United States
(12) Patent Application Publication
(10) Pub. No.: US 2005/0161808 A1
(43) Pub. Date: Jul. 28, 2005

(54) Wafer, intermediate wafer assembly and associated method for fabricating a silicon on insulator wafer having an improved edge profile

(76) Inventor: Douglas G. Anderson, Vancouver, WA (US)

Correspondence Address: ALSTON & BIRD LLP;BANK OF AMERICA PLAZA, 101 SOUTH TRYON STREET, SUITE 4000, CHARLOTTE, NC, 28280-4000, US

(21) Appl. No.: 10/762,789

(22) Filed: Jan. 22, 2004

(51) Int. Cl. H01L 23/04; H01L 21/30

(52) U.S. Cl. 257/730; 438/459

(57) ABSTRACT

A wafer, an intermediate wafer assembly and an improved method of fabricating a wafer having an improved edge profile are provided. The wafer may have various edge profiles that eliminate, or at least reduce, the chamfered portion proximate one of the major surfaces. For example, the wafer may have an edge with curved surface extending continuously from one major surface to another, an angled edge segment adjacent one major surface and a curved surface extending from the angled edge segment to the other major surface, or first and second angled edge segments adjacent the opposed major surfaces and a curved surface extending therebetween with the second angled edge segment being at least 50% smaller in a radial direction than the first angled edge segment. The wafer may serve as the bonded wafer, the handle wafer, or both the bonded and handle wafers of an SOI wafer.

### BACKGROUND OF THE INVENTION

The present invention relates generally to wafers, including silicon on insulator (SOI) wafers, and associated fabrication methods and, more particularly, to wafers, including SOI wafers, and corresponding methods for fabricating wafers having an improved edge profile.

Wafers, such as silicon wafers and, more particularly, silicon on insulator (SOI) wafers, form the substrate upon which a variety of semiconductor devices are fabricated. In order to ensure that the semiconductor devices perform properly, wafers must generally be fabricated to exacting specifications and must be free of any significant manufacturing defects. During a typical wafer fabrication process, wafers are sliced from an ingot. Thereafter, the wafer edge is ground to size the wafer to an exact diameter and to form the edges into a preferred geometric shape. The opposed major surfaces of the wafer are then lapped in order to planerize the wafer by reducing thickness variations and improving flatness across each major surface. The opposed surfaces are then etched in order to reduce surface defects. The wafer edge may also be etched. Thereafter, the wafers may be rinsed, thermally processed and inspected. Following inspection, the edges and at least the front surface are polished such that the resulting surfaces have a mirror-like finish suitable for device fabrication.

In grinding the edge of the wafer, chamfered portions are generally ground proximate each of the opposed major surfaces of the wafer. Typically, these chamfered portions are identical such that the chamfered portion proximate one major surface is the same as the chamfered portion of proximate the opposed major surface. The chamfered portions are generally ground to define a chamfered edge surface that extends at a predefined angle relative to the respective major surface. While wafers may include chamfered edges that extend at a variety of different angles, wafers frequently include chamfered portions that define chamfered edge surfaces that extend at a predefined angle of 22° relative to the respective major surfaces. By chamfering those portions of the edge proximate the opposed major surfaces, the wafer is less susceptible to edge chipping, since the resulting wafer does not include a sharp corner, such as a corner defining an angle of about 90°, proximate either major surface.

One type of wafer that is gaining in popularity is an SOI wafer. In a SOI wafer, a bonded wafer is attached, such as by means of an oxide layer, to an underlying handle wafer. Both wafers may be formed of the same material, such as silicon, although the bonded wafer may include a dopant so as to be semiconductive, while the handle wafer remains insulative. Thereafter, the bonded wafer may be thinned and various semiconductor devices may be fabricated in the active layer that remains following thinning of the bonded wafer.

Both the bonded wafer and the handle wafer of an SOI wafer generally have the same edge profile. In this regard, both the bonded wafer and the handle wafer typically include a chamfered portion proximate each opposed major surface. For example, FIG. 1 depicts a conventional SOI wafer 10 having a bonded wafer 12 that is attached to a handle wafer 14 by means of an oxide layer 16, prior to thinning of the bonded wafer. As shown, the oxide layer may only be disposed upon the major surface of the handle wafer that faces the bonded wafer. Alternatively, the oxide layer may be disposed on all surfaces of the handle wafer, including both of the opposed major surfaces. The bonded and handle wafers each generally include chamfered edge portions 18 proximate the opposed major surfaces. Because of the chamfered edge portions of the SOI wafers, and, in particular, the chamfered edge portions of the bonded wafer, the thinning of the bonded wafer results in an active layer that is smaller than the initial diameter of the wafer. In this regard, the bonded wafer is generally thinned such that the chamfered edge portion proximate the exposed major surface, i.e., the major surface facing away from the handle wafer, and the intermediate edge surface are removed. Moreover, the edge of the bonded wafer that remains after thinning is generally reshaped as shown in FIG. 2 so as to have a generally frustoconical shape such that the active layer 20 does not extend radially outward beyond the major surface that faces and is attached to the handle wafer. During the reshaping of the edge, the edge of the bonded wafer is typically ground in a radially inward direction so as to reduce the diameter of the bonded wafer by between about 1 mm and 3 mm.

The reduction in the size of the active layer relative to the initial size of the wafer reduces the number of semiconductor devices that may be fabricated upon the SOI wafer. Additionally, the reduction in the size of the active layer of the SOI wafer causes the SOI wafer to have a smaller diameter than a conventional wafer.

In order to increase the size of the active layer and to avoid the deleterious effects associated with further processing of an undersized wafer, one could begin with oversized wafers, that is, wafers having a diameter larger than a conventional wafer. The amount of the oversizing could be established such that the subsequent thinning and edge grinding creates an SOI wafer having a diameter substantially equal to the diameter of a conventional wafer and a correspondingly larger active layer. Thus, the resulting SOI wafer could be processed in a conventional manner without increased concern regarding edge chipping or the like. However, the fabrication of oversized wafers is itself an expensive proposition requiring substantial modification in the tooling and other equipment required to grow ingots having a larger diameter and to subsequently process the oversized ingots to form the oversized bonded and handle wafers, as well as the additional costs of silicon that will ultimately be ground away and discarded.

As such, it would be desirable to fabricate wafers, such as SOI wafers, having a larger active layer in which to form semiconductor devices without having to initially fabricate oversized wafers. In addition, it would be desirable to fabricate wafers, such as SOI wafers, having larger active layers in accordance with conventional fabrication techniques without increasing the possibility of edge chipping or other deleterious effects that is occasioned by the processing of undersized wafers.

### BRIEF SUMMARY OF THE INVENTION

A wafer, an intermediate wafer assembly and an associated method of fabrication are hereby disclosed to provide an improved edge profile. The improved edge profile of the wafer permits the size of the active layer to be increased without requiring that the wafer initially be oversized. The improved edge profile also permits the edge of the wafer to be ground so as to form a larger active layer without causing the wafer to be undersized, thereby advantageously permitting the resulting wafer to be processed in a conventional fashion. While a variety of wafers may incorporate the improved edge profile, the improved edge profile is particularly advantageous for SOI wafers.

A wafer is therefore provided according to one aspect of the present invention that includes a substrate having opposed first and second major surfaces and a peripheral edge extending therebetween that has an improved cross-sectional profile. The cross-sectional profile of the edge includes an angled edge segment adjacent the first major surface that extends linearly at a predefined angle relative to a reference plane defined by the first major surface. The cross-sectional profile of the edge also includes a curved edge segment that defines a continuous curve, such as a radiused surface, extending from the angled edge segment to the second major surface. As a result of the curvature of the curved edge surface, the second major surface of the wafer has a smaller diameter than the medial portion of the substrate between the first and second major surfaces. For example, the diameter of the second major surface may be between 100 microns and 300 microns smaller in diameter than that portion of the substrate having the largest diameter. Additionally, the first major surface may have a smaller diameter than the diameter of the second major surface as a result of the angled edge segment proximate thereto.

A method of fabricating a wafer having an improved cross-sectional profile is also provided according to another aspect of the present invention. In this regard, a portion of the edge adjacent the first major surface is ground to form the angled edge segment extending linearly at the predefined angle relative to a reference plane defined by the first major surface. Additionally, another portion of the edge is ground to form the curved edge segment that defines a continuous curve, such as radiused surface, extending from the angled edge segment to the second major surface. The curved edge segment may be ground such that the second major surface has a smaller diameter, such as between 100 microns and 300 microns smaller, than a medial portion of the wafer between the first and second major surfaces. Additionally, the angled edge segment and the curved edge segment may be ground such that the first major surface has a smaller diameter than the second major surface.

According to another aspect of the present invention, an intermediate wafer assembly is provided that includes a handle wafer and a bonded wafer attached to the handle wafer so that at least the bonded wafer and, in some embodiments, both the bonded wafer and the handle wafer have an improved edge profile. In this regard, the handle wafer and the bonded wafer may each include a respective edge that defines a radiused surface that extends continuously to the interface between the handle and bonded wafers. As a result of the radiused surface, the major surface that is proximate the interface may have a smaller diameter than a medial portion of the respective wafer between the opposed major surfaces. For example, the diameter of the major surface of each wafer that is proximate the interface may be between 100 microns and 300 microns smaller than the portion of the respective wafer having the largest diameter. Each respective wafer may also include an angled edge segment, adjacent to the major surface opposite the interface, that extends linearly at a predefined angle relative to the reference plane defined by the respective major surface. Thus, the major surface opposite the interface may have a smaller diameter than the diameter of the major surface proximate the interface.

A method for fabricating an SOI wafer is also provided according to another aspect of the present invention that includes grinding the edge of each of a handle wafer and a bonded wafer to form radiused surfaces that extend continuously to at least one major surface of the respective wafer, and bonding the handle and bonded wafers so that the respective radiused surfaces extend continuously to an interface between the handle and bonded wafers such that the major surface of each wafer that is proximate one interface has a smaller diameter than a medial portion of the respective wafer between the opposed major surfaces. The method may also include the step of grinding the edges of the handle and bonded wafers following the bonding of the handle and bonded wafers such that the resulting SOI wafer has a diameter that is no larger than the diameter of the major surface of each wafer that is proximate the interface. In this regard, the edges of the handle and bonded wafers may be initially ground such that the diameter of the respective major surface proximate the interfaces is between 100 microns and 300 microns smaller than the diameter of that portion of the respective wafer having the largest diameter. The method of fabricating the SOI wafer may also include grinding a portion of the edge of each of the handle and bonded wafers that is adjacent to the major surface that is opposite to the interface to form an angled edge segment that extends at a predefined angle relative to a reference plane defined by the respective major surface. As such, the major surface of each wafer that is opposite the interface may have a smaller diameter than the diameter of the major surface proximate the interface.

According to another aspect of the present invention, an intermediate wafer assembly is provided that includes a handle wafer and a bonded wafer attached to the handle wafer and having an improved cross-sectional profile including first and second angled edge segments proximate the opposed major surfaces and a curved edge segment extending therebetween. The first angled edge segment is adjacent the first major surface that faces away from the handle wafer. The first angled edge segment extends linearly at a predefined angle relative to a reference plane defined by the first major surface. The second angled edge segment is adjacent the second major surface that is proximate the handle wafer. The second angled edge segment extends linearly at a predefined angle relative to a reference plane defined by the second major surface. This second angled edge segment is at least 50% smaller in a radial direction than the first angled edge segment, such that the diameter of the second major surface is correspondingly larger than the diameter of the first major surface. Additionally, the curved edge segment defines a continuous curve, such as a radiused surface, extending between the first and second angled edge segments. In one embodiment, the handle wafer also has the same cross-sectional edge profile as the bonded wafer including the first and second angled edge segments and the curved edge segment extending therebetween.

By including a second angled edge segment, the risk of edge chipping proximate the second major surface is reduced. By substantially reducing the size of the second angled edge segment relative to the first angled edge segment, however, the size of the resulting active layer is advantageously increased relative to conventional designs.

A method of fabricating an SOI wafer is also provided in which the edge of the bonded wafer is ground to have a first angled edge segment adjacent the first major surface, a second angled edge segment adjacent the second major surface that is at least 50% smaller in a radial direction than the first angled edge segment, and a curved edge segment defining a continuous curve, such as a radiused surface, extending between the first and second angled edge segments. The bonded wafer may then be bonded to a handle wafer such that the second angled edge segment is proximate the handle wafer. The edge of the handle wafer may also be ground in a corresponding manner so as to have first and second angled edge segments and a curved edge segment extending therebetween.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a side view of a conventional silicon on insulator (SOI) wafer prior to thinning of the bonded wafer;

FIG. 2 is a side view of a conventional SOI wafer following thinning of the bonded wafer;

FIG. 3 is a side view of an SOI wafer according to one embodiment of the present invention in which both the handle and bonded wafers include an angled edge segment and a curved edge segment;

FIG. 4 is a side view of an SOI wafer according to another embodiment of the present invention in which both the handle and bonded wafers include a curved edge segment;

FIG. 5 is a side view of an SOI wafer of FIG. 4 following thinning of the bonded wafer and edge grinding of the SOI wafer; and

FIG. 6 is a side view of an SOI wafer according to a further embodiment of the present invention in which both the handle and bonded wafers include first and second angled edge segments and a curved edge segment therebetween.

### DETAILED DESCRIPTION OF THE INVENTION

The present inventions now will be described more fully hereinafter with reference to the accompanying drawings, in which some, but not all embodiments of the invention are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

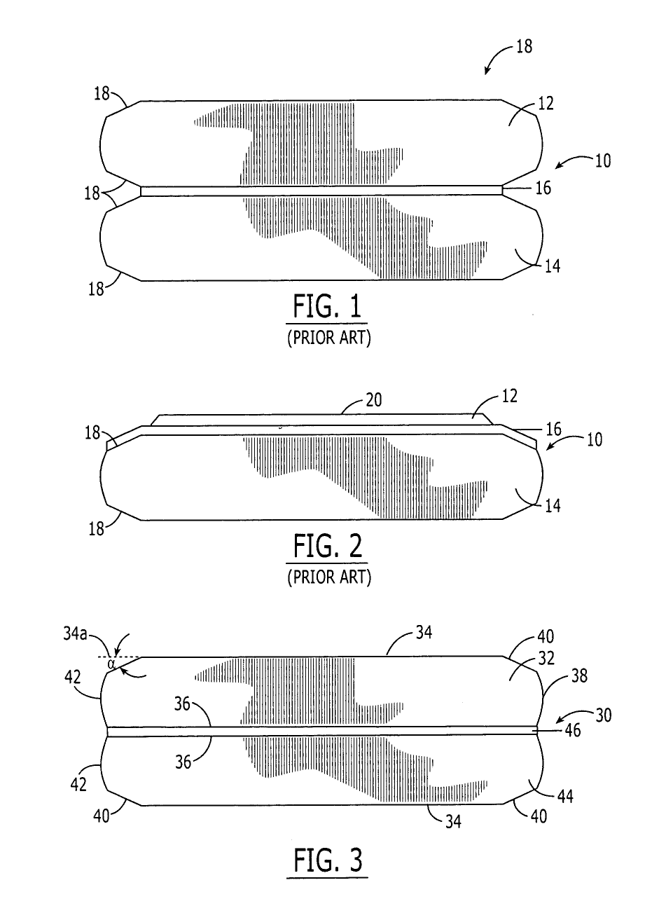

As shown in FIG. 3, a wafer 30 according to one aspect of the present invention is depicted. The wafer includes a substrate 32 having opposed first and second major surfaces 34, 36 and a peripheral edge 38 extending between the first and second wafer surfaces. The substrate may be formed of various materials, but is typically formed of silicon. According to the present invention, the cross-sectional profile of the edge is redesigned which offers numerous advantages, particularly during fabrication of a silicon on insulator (SOI) wafer. Among other advantages, the improved cross-sectional profile of the edge of the wafer of the present invention permits the resulting wafer to have a conventional size while increasing the size of the active layer without requiring that the wafer initially be oversized.

As shown in FIG. 3, the cross-sectional profile of the edge 38 includes an angled edge segment 40 adjacent the first major surface 34. The angled edge segment extends linearly at a predefined angle α, such as 22°, relative to a reference plane 34a defined by the first major surface. As will be apparent, the angled edge segment has a frustoconical shape which appears as a pair of opposed linear segments in the cross-sectional view of FIG. 3. By chamfering the edge to have an angled edge segment adjacent the first major surface, the risk of edge chipping or the like is reduced in comparison to a wafer having a sharp corner, such as a corner defining about a 90° angle, between the first major surface and the edge.

The cross-sectional profile of the edge 38 of this embodiment also includes a curved edge segment 42 that defines a continuous curve extending from the angled edge segment 40 to the second major surface 36. Typically, the continuous curve is a radiused surface with the radius taken about a point in the center of the wafer 30, both radially and in a thickness direction. However, the radiused surface may be centered about other points, if so desired. For example, the radiused surface may be taken about a point central to the thickness of the curved edge segment rather than the thickness of the wafer. The second major surface typically has a smaller diameter than the medial portion of the substrate between the first and second surfaces. For example, the diameter of the second major surface may be between 100 microns and 300 microns, such as about 200 microns, smaller than the diameter of that portion of the substrate having the largest diameter. As a result of the angled edge segment, however, the first major surface 34 generally has a smaller diameter than that of the second major surface.

While a wafer 30 as described above may be used for various applications, the wafer may comprise a bonded wafer of an SOI wafer as shown in FIG. 3. In this regard, an SOI wafer includes a bonded wafer attached to a handle wafer 44. Both the bonded and the handle wafers are generally formed of the same material, such as silicon, but the bonded wafer typically includes a dopant such that the bonded wafer is a semiconductor while the handle wafer remains insulative. The bonded wafer may be attached to the handle wafer by various manners including by means of an oxide layer 46. As shown in FIG. 3, both the bonded wafer and the handle wafer may have edges with the same cross-sectional profile as described above. As such, the bonded and handle wafers are attached such that the angled edge segment 40 of each wafer is proximate the respective major surface 34 that faces away from, i.e., is opposed to, the other wafer. In other embodiments, however, only the bonded wafer has the cross-sectional edge profile described above and the handle wafer has a more conventional edge profile in which angled edge segments are defined proximate both of the opposed major surfaces.

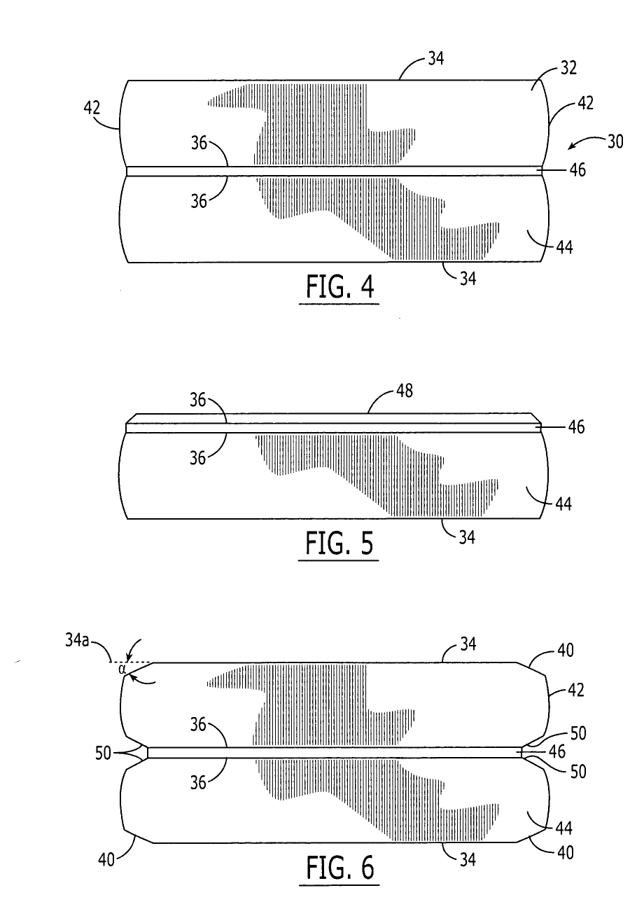

As shown in FIG. 4, the wafer 30 of another embodiment of the present invention need not include the angled edge segment, but may, instead, include a curved edge segment 42 that defines a continuous curve, such as a radiused surface, that extends between the opposed first and second major surfaces 34, 36. In the same manner as described above, the curved edge segment is such that the second major surface has a smaller diameter, typically by between 100 microns and 300 microns, then a medial portion of the substrate between the first and second major surfaces. The wafer of this embodiment may also serve as the bonded wafer, the handle wafer or both the bonded and handle wafers of an SOI wafer as shown in FIG. 4.

The SOI wafers depicted in FIGS. 3 and 4 are intermediate wafer assemblies. In other words, the SOI wafers depicted in FIGS. 3 and 4 are shown prior to thinning of the bonded wafer 30. In order to fabricate the intermediate wafer assembly of FIGS. 3 and 4, the edge 38 of the bonded wafer is ground to define the continuous curve, such as the radiused surface. In those embodiments in which the edge of the bonded wafer also includes an angled edge segment 40, the edge of the bonded wafer is also ground to form the angled edge segment at the predefined angle relative to the reference plane 34a defined by the first major surface 34. The edge of the handle wafer 44 is also appropriately ground. In instances in which the handle wafer is to have the same edge profile as the bonded wafer, the edge of the handle wafer is ground to define the continuous curve, such as the radiused surface and, in some embodiments, an angled edge segment adjacent the first major surface of the handle wafer. The bonded and handle wafers are then attached, such as by means of an oxide layer 46, such that the first major surfaces of the bonded and handle wafer are opposed to one another as shown in FIG. 3.

Regardless of whether the bonded and/or handle wafers include an angled edge segment 40 as shown in FIG. 3 or whether the edge surface defines a continuous curve extending between the opposed major surfaces 34, 36 as shown in FIG. 4, the intermediate wafer assembly is further processed. In this regard, the bonded wafer 30 is thinned, such as by surface grinding and polishing the first major surface of the bonded wafer in order to remove material until the bonded wafer is thinned to a predetermined thickness. The edge surface of that portion of the bonded wafer that remains is then ground to remove the radial outermost portions of the bonded and handle wafers 30, 44 that extend beyond the oxide layer 46 that attaches the respective second major surfaces of the bonded and handle wafers together. In this regard, FIG. 5 depicts the SOI wafer of FIG. 4 once the bonded wafer has been thinned and the edge of the SOI wafer has been ground.

By forming the bonded and handle wafers 30, 44 such that the curved edge segment 42 extends to the second major surface 36, the size of the second major surface can be increased and, in turn, the size of the active layer 48 of the resulting SOI wafer can be increased relative to conventional SOI wafers, as shown in FIGS. 1 and 2, having an angled edge segment proximate the second major surface. By increasing the size of the active layer, the number of semiconductor devices that may be fabricated upon the active layer is advantageously increased. Additionally, the fabrication of the SOI wafer is facilitated since the extent by which the edges 38 of the bonded and handle wafers must be ground is reduced relative to conventional SOI wafers. Moreover, since the SOI wafer is only reduced by between 100 microns and 300 microns in diameter during the edge grinding process, both the intermediate wafer assembly that exists prior to thinning of the bonded wafer as shown in FIGS. 3 and 4 and the resulting SOI wafer, such as shown in FIG. 5 can be conventionally sized. As such, the wafers can be advantageously grown with conventional tooling and other equipment.

Although it is desirable in many respects to define the edge profile of the wafer 30 in a manner that maximizes the size of the second major surface 36, i.e., the major surface that will be attached to the other wafer of an SOI wafer, it is sometimes desirable to have a second angled edge segment 50 proximate the second major surface. In this regard, the corner defined between the curved edge segment 42 and the second major surface may, in some instances, create an increased risk of edge chipping and/or may otherwise make wafer handling more difficult than conventional wafers having chamfered corners. As shown in the embodiment of FIG. 6, therefore, the edge 38 of the wafer may be ground to define not only a first angled edge segment 40 adjacent the first major surface 34 that extends linearly at a predefined angle relative to the reference plane 34a defined by the first major surface, but also a second angled edge segment adjacent the second major surface that extends linearly at a predefined angle α relative to the reference plane 36a defined by the second major surface. As shown, the second angled edge segment is substantially smaller than the first angled edge segment such that the second major surface remains larger than the first major surface. In one advantageous embodiment, the second angled edge segment is at least 50% smaller in a radial direction than the first angled edge segment. Additionally, while the first and second edge segments are shown to be disposed at the same angle α, such as 22°, the first and second edge segments may define different angles relative to the reference plane defined by the respective major surface. The edge of the wafer of this embodiment may also include a curved edge segment 42 that extends between the first and second angled edge segments so as to define a continuous curve, such as a radiused surface, therebetween.

As shown in FIG. 6, a wafer 30 of this embodiment that includes first and second angled edge segments 40, 50 and a curved edge segment 42 therebetween may serve as the bonded wafer, the handle wafer or both the bonded and handle wafers of an SOI wafer. In the embodiment of FIG. 6, both the bonded and handle wafers have the same edge profile and, in particular, both the bonded and handle wafers include edges 38 having first and second angled edge segments and a curved edge segment therebetween. However, either the bonded wafer or the handle wafer could have an edge having both first and second angled edge segments and a curved edge segment therebetween, while the other wafer has another edge profile.

Although not depicted, the intermediate wafer assembly of FIG. 6 would typically be processed in the manner described above in conjunction with FIG. 5 including the thinning of the bonded wafer 30 and the grinding of the edges of the bonded and handle wafers. While the edge of the SOI wafer depicted in FIG. 6 would generally be ground somewhat more than the wafers depicted in FIGS. 3 and 4 as a result of the second angled edge segment 50, the SOI wafer of FIG. 6 would still require less edge grinding than a conventional SOI wafer in which the edges of both the bonded and handle wafers include first and second angled edge segments that are identical in size. In this regard, the SOI wafer would need to be edge ground to remove the second angled edge segment such that the resulting SOI wafer does not include any indentation or valley between the bonded and handle wafers that could serve as a separation plane. However, by reducing the size of the second angled edge segment in a radial direction relative to the first angled edge segment 40, the extent of the edge grinding is correspondingly reduced and the size of the resulting active layer is similarly increased, thereby permitting more semiconductor devices to be fabricated in the active layer than allowed by conventional SOI wafers. Additionally, by reducing the size of the second angled edge segment, both the original wafer and the SOI wafer that is produced following thinning of the bonded wafer and edge grinding may have a conventional size and therefore do not require different tooling.

While the active layer of the resulting SOI wafer may be somewhat smaller than the active layer of the SOI wafers of the embodiments of FIGS. 3 and 4, the introduction of a second angled edge segment 50 proximate the second major surface 36 may reduce the possibility of edge chipping at the corner defined between the edge 38 and the second major surface of the wafer 30. Moreover, the inclusion of a second angled edge segment may facilitate prior polishing and/or lapping steps in which water is sometimes applied by a water knife under the second angled edge segment in order to release the wafer from the polishing plate.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A wafer comprising:
a substrate having opposed first and second major surfaces and a peripheral edge extending therebetween, wherein a cross-sectional profile of the edge comprises:
an angled edge segment adjacent the first major surface that extends linearly at a predefined angle relative to a reference plane defined by the first major surface; and
a curved edge segment that defines a continuous curve extending from the angled edge segment to the second major surface.

2. A wafer according to claim 1 wherein the curved edge segment comprises a radiused surface extending from the angled edge segment to the second major surface.

3. A wafer according to claim 1 wherein the second major surface has a smaller diameter than a medial portion of said substrate between said first and second major surfaces.

4. A wafer according to claim 3 wherein the diameter of the second major surface is between 100 microns and 300 microns smaller than a diameter of that portion of said substrate having the largest diameter.

5. A wafer according to claim 1 wherein the first major surface has a smaller diameter than a diameter of the second major surface.

6. An intermediate wafer assembly comprising:
a handle wafer; and
a bonded wafer attached to said handle wafer,
wherein said handle wafer and said bonded wafer each include a respective edge extending peripherally thereabout, and wherein the edge of each respective wafer defines a radiused surface that extends continuously to an interface between said handle and bonded wafers.

7. An intermediate wafer assembly according to claim 6 wherein each wafer comprises opposed major surfaces, and wherein the major surface of each wafer that is proximate the interface has a smaller diameter than a medial portion of the respective wafer between the opposed major surfaces.

8. An intermediate wafer assembly according to claim 7 wherein the diameter of the major surface of each wafer that is proximate the interface is between 100 microns and 300 microns smaller than a diameter of that portion of the respective wafer having the largest diameter.

9. An intermediate wafer assembly according to claim 6 wherein each wafer comprises opposed major surfaces, and wherein a cross-sectional profile of the edge of each respective wafer also includes an angled edge segment, adjacent the major surface opposite the interface, that extends linearly at a predefined angle relative to a reference plane defined by the respective major surface.

10. An intermediate wafer assembly according to claim 9 wherein the major surface opposite the interface has a smaller diameter than a diameter of the major surface proximate the interface.

11. An intermediate wafer assembly comprising:
a handle wafer; and
a bonded wafer attached to said handle wafer, said bonded wafer having a first major surface facing away from said handle wafer, a second major surface proximate said handle wafer, and a peripheral edge extending between the first and second major surfaces, wherein a cross-sectional profile of the edge comprises:
a first angled edge segment adjacent the first major surface that extends linearly at a predefined angle relative to a reference plane defined by the first major surface;
a second angled edge segment adjacent the second major surface that extends linearly at a predefined angle relative to a reference plane defined by the second major surface, wherein the second angled edge segment is at least 50% smaller in a radial direction than the first angled edge segment such that the diameter of the second major surface is correspondingly larger than the diameter of the first major surface; and
a curved edge segment that defines a continuous curve extending between the first and second angled edge segments.

12. An intermediate wafer assembly according to claim 11 wherein the curved edge segment of said bonded wafer comprises a radiused surface extending between the first and second angled edge segments.

13. An intermediate wafer assembly according to claim 11 wherein said handle wafer also has a first major surface facing away from said bonded wafer, a second major surface proximate said bonded wafer, and a peripheral edge extending between the first and second major surfaces, wherein a cross-sectional profile of the edge comprises:
a first angled edge segment adjacent the first major surface that extends linearly at a predefined angle relative to a reference plane defined by the first major surface;
a second angled edge segment adjacent the second major surface that extends linearly at a predefined angle relative to a reference plane defined by the second major surface, wherein the second angled edge segment is at least 50% smaller in a radial direction than the first angled edge segment such that the diameter of the second major surface is correspondingly larger than the diameter of the first major surface; and
a curved edge segment that defines a continuous curve extending between the first and second angled edge segments.

14. A method fabricating a wafer having opposed first and second major surfaces and a peripheral edge extending therebetween, the method comprising:
grinding a portion of the edge adjacent to the first major surface to form an angled edge segment that extends linearly at a predefined angle relative to a reference plane defined by the first major surface; and
grinding another portion of the edge to form a curved edge segment that defines a continuous curve extending from the angled edge segment to the second major surface.

15. A method according to claim 14 wherein grinding another portion of the edge comprises grinding another portion of the edge to form the curved edge segment that comprises a radiused surface extending from the angled edge segment to the second major surface.

16. A method according to claim 14 wherein grinding another portion of the edge comprises grinding another portion of the edge to form the curved edge segment such that the second major surface has a smaller diameter than a medial portion of the wafer between the first and second major surfaces.

17. A method according to claim 16 wherein grinding another portion of the edge comprises grinding the edge such that the diameter of the second major surface is between 100 microns and 300 microns smaller than a diameter of that portion of said substrate having the largest diameter.

18. A method according to claim 14 wherein the grinding steps comprise grinding the edge such that the first major surface has a smaller diameter than a diameter of the second major surface.

19. A method of fabricating a silicon on insulator (SOI) wafer comprising:
grinding an edge of a handle wafer to form a radiused surface that extends continuously to one major surface of the handle wafer;
grinding an edge of a bonded wafer to form a radiused surface that extends continuously to one major surface of the bonded wafer; and
bonding the handle wafer and the bonded wafer such that the respective radiused surfaces extend continuously to an interface between the handle and bonded wafers.

20. A method according to claim 19 wherein each wafer comprises opposed major surfaces, wherein the major surface of each wafer that is proximate the interface has a smaller diameter than a medial portion of the respective wafer between the opposed major surfaces, and wherein the method further comprises additionally grinding the edges of the handle and bonded wafers following the bonding of the handle and bonded wafers such that the resulting SOI wafer has a diameter that is no larger the diameter of the major surface of each wafer that is proximate the interface prior to the additional grinding.

21. A method according to claim 20 wherein the grinding steps comprise grinding the edge of the respective wafer such that the diameter of the major surface proximate the interface is between 100 microns and 300 microns smaller than a diameter of that portion of the respective wafer having the largest diameter.

22. A method according to claim 19 wherein each wafer comprises opposed major surfaces, and wherein the method further comprises:
grinding a portion of the edge of the handle wafer adjacent the major surface that is opposite the interface to form an angled edge segment that extends linearly at a predefined angle relative to a reference plane defined by the respective major surface; and
grinding a portion of the edge of the bonded wafer adjacent the major surface that is opposite the interface to form an angled edge segment that extends linearly at a predefined angle relative to a reference plane defined by the respective major surface.

23. A method of claim 22 wherein the grinding steps comprise grinding the edge of each wafer such that the major surface opposite the interface has a smaller diameter than a diameter of the major surface proximate the interface.

24. A method of fabricating a silicon on insulator (SOI) wafer comprising:
grinding an edge of a bonded wafer that extends between opposed first and second major surfaces and peripherally thereabout, wherein grinding the edge of the bonded wafer comprises:
grinding a first angled edge segment adjacent the first major surface that extends linearly at a predefined angle relative to a reference plane defined by the first major surface;
grinding a second angled edge segment adjacent the second major surface that extends linearly at a predefined angle relative to a reference plane defined by the second major surface, wherein the second angled edge segment is at least 50% smaller in a radial direction than the first angled edge segment such that the diameter of the second major surface is correspondingly larger than the diameter of the first major surface; and
grinding a curved edge segment that defines a continuous curve extending between the first and second angled edge segments; and
bonding the bonded wafer to a handle wafer such that the second angled edge segment is proximate the handle wafer.

25. A method according to claim 24 wherein grinding the curved edge segment comprises grinding a radiused surface extending between the first and second angled edge segments.

26. A method according to claim 24 wherein said handle wafer also has a first major surface facing away from the bonded wafer, a second major surface proximate the bonded wafer, and a peripheral edge extending between the first and second major surfaces, wherein the method further comprises grinding the edge of the handle wafer, and wherein grinding the edge of the handle wafer comprises:
grinding a first angled edge segment adjacent the first major surface that extends linearly at a predefined angle relative to a reference plane defined by the first major surface;
grinding a second angled edge segment adjacent the second major surface that extends linearly at a predefined angle relative to a reference plane defined by the second major surface, wherein the second angled edge segment is at least 50% smaller in a radial direction than the first angled edge segment such that the diameter of the second major surface is correspondingly larger than the diameter of the first major surface; and
grinding a curved edge segment that defines a continuous curve extending between the first and second angled edge segments.
